(19) United States
(12) Patent Application Publication
(10) Pub. No.: US 2016/0124147 A1
(43) Pub. Date: May 5, 2016

(54) SEMICONDUCTOR-BASED PHOTODETECTOR HAVING MULTIPLE OPTICAL FEEDS FOR COUPLING LIGHT INTO AN ACTIVE AREA THEREOF

(71) Applicant: Alcatel-Lucent USA Inc., Murray Hill, NJ (US)

(72) Inventors: Chia-Ming Chang, Matawan, NJ (US); Jeffrey H. Sinsky, Marlboro, NJ (US)

(73) Assignee: ALCATEL-LUCENT USA INC., Murray Hill, NJ (US)

(21) Appl. No.: 14/879,196

(22) Filed: Oct. 9, 2015

Related U.S. Application Data
(60) Provisional application No. 62/063,435, filed on Oct. 14, 2014.

(51) Int. Cl. G02B 6/12; H01L 31/0232

(52) U.S. Cl. CPC G02B 6/12004; H01L 31/02327; G02B 2006/12138; G02B 2006/12147; G02B 2006/1215; G02B 2006/12154; G02B 2006/12123

(57) ABSTRACT

We disclose a semiconductor-based photodetector having multiple optical feeds for coupling light into an active area thereof in a manner that causes the light to be distributed more-uniformly therein than in a comparable conventional photodetector. As a result, embodiments of the disclosed photodetector can handle an advantageously high optical power and generate a relatively high photocurrent before the saturation is reached. In some embodiments, the multiple optical feeds are used to reduce the size of the active area to achieve a larger effective bandwidth and/or better RF response for the photodetector without exacerbating certain detrimental effects therein, e.g., caused by the excessive heat generated by the absorbed light. In some embodiments, multiple semiconductor-based photodetectors can be optically arrayed and electrically interconnected to form a traveling-wave photodetector that preserves one or more beneficial characteristics of the individual photodetectors used therein.

### CROSS-REFERENCE TO RELATED APPLICATIONS

This application claims priority from U.S. Provisional Patent Application No. 62/063,435 filed on Oct. 14, 2014, and entitled “SEMICONDUCTOR-BASED PHOTODETECTOR HAVING AN OPTICAL MULTI-FEED STRUCTURE FOR COUPLING LIGHT INTO AN ACTIVE AREA THEREOF,” which is incorporated herein by reference in its entirety.

### BACKGROUND

1. Field

The present disclosure relates to electro-optical circuits and, more specifically but not exclusively, to semiconductor-based photodetectors and photodetector arrays.

2. Description of the Related Art

This section introduces aspects that may help facilitate a better understanding of the disclosure. Accordingly, the statements of this section are to be read in this light and are not to be understood as admissions about what is in the prior art or what is not in the prior art.

Traveling-wave photodetectors (TWPDs) can be used, e.g., in modern broadband optical communication systems. A desirable characteristic of a TWPD is the ability to maintain relatively high efficiency and relatively broad bandwidth when exposed to a relatively strong (e.g., high-power or high-intensity) radio-frequency (RF)-modulated optical signal. Such optical signals are becoming relatively prevalent at optical receivers, e.g., due to the continued drive for miniaturization and integration of the electro-optical circuits employed therein and the wide use of optical amplification in the corresponding optical transport links. As a result, TWPDs having the above-mentioned and other desirable characteristics for commercial telecom applications are being actively developed.

### SUMMARY OF SOME SPECIFIC EMBODIMENTS

Disclosed herein are various embodiments of a semiconductor-based photodetector having multiple optical feeds for coupling light into an active area thereof in a manner that causes the light to be distributed more-uniformly therein than in a comparable conventional photodetector. As a result, embodiments of the disclosed photodetector can handle an advantageously high optical power and generate a relatively high photocurrent before the saturation is reached.

In some embodiments, the multiple optical feeds are used to reduce the size of the active area to achieve a larger effective bandwidth and/or better RF response for the photodetector without exacerbating certain detrimental effects therein, e.g., caused by the excessive heat generated by the absorbed light.

In some embodiments, multiple semiconductor-based photodetectors can be optically arrayed and electrically interconnected to form a traveling-wave photodetector that preserves one or more beneficial characteristics of the individual photodetectors used therein.

According to an example embodiment, provided is an apparatus comprising: a photodiode that comprises an active semiconductor layer; a first optical waveguide configured to couple light into a first portion of the active semiconductor layer; and a second optical waveguide configured to couple light into a second portion of the active semiconductor layer different from the first portion.

### BRIEF DESCRIPTION OF THE DRAWINGS

Other aspects, features, and benefits of various disclosed embodiments will become more fully apparent, by way of example, from the following detailed description and the accompanying drawings, in which:

FIG. 1 shows a block diagram of a photodetector according to an embodiment of the disclosure;

FIGS. 2A-2D show various schematic views of a semiconductor device that can be used to implement the photodetector of FIG. 1 according to an embodiment of the disclosure;

FIG. 3 graphically shows example results of computer simulations corresponding to the semiconductor device of FIG. 2 according to an embodiment of the disclosure;

FIG. 4 shows a block diagram of a photodetector according to an alternative embodiment of the disclosure;

FIG. 5 shows a schematic top view of a semiconductor device that can be used to implement the photodetector of FIG. 4 according to an embodiment of the disclosure;

FIG. 6 shows a schematic top view of a planar electro-optical circuit that incorporates the semiconductor device of FIG. 5 according to an embodiment of the disclosure;

FIG. 7 shows a block diagram of a photodetector according to another alternative embodiment of the disclosure;

FIG. 8 shows a schematic top view of a semiconductor device that can be used to implement the photodetector of FIG. 7 according to an embodiment of the disclosure;

FIG. 9 shows a block diagram of a traveling-wave photodetector circuit according to an embodiment of the disclosure; and

FIG. 10 shows a schematic top view of a semiconductor device that can be used to implement a photodetector array used in the circuit of FIG. 9 according to an embodiment of the disclosure.

### DETAILED DESCRIPTION

An example embodiment of a photodetector disclosed herein is designed to take advantage of silicon photonic integration and be used for high-power and/or high-speed applications. For the photodetector to be able to handle a relatively high total optical-input power, the active photodiode area of such a photodetector is provided with multiple optical feeds, each coupled to a respective optical waveguide and configured to illuminate a different respective portion of the active photodiode area. A high-power, RF-modulated optical-input signal is optically split into multiple (attenuated) copies that are then applied to the multiple optical feeds through the corresponding optical waveguides. The optical multi-feed structure advantageously enables the high power of the optical input signal to be distributed more-uniformly over the active photodiode area of the photodetector compared to the optical-power distribution achieved with a conventional single-feed/single-waveguide structure. As a result, the disclosed photodetector can handle higher optical power and generate higher photocurrent before a saturation level is reached than a comparable conventional photodetector.

For relatively high (e.g., >10 GHz) RF-modulation frequencies, it may be beneficial to make the photodiode area in the photodetector as small as possible. The reduced active area might help, e.g., to reduce the electrical parasitic effects that tend to decrease the bandwidth of the corresponding photodetector. Advantageously, various embodiments of the optical multi-feed structure disclosed herein can be used to significantly increase the power-handling capability of the host photodetector while only slightly increasing the device size with respect to a conventional photodiode designed with similar technical constrains in mind. As a result, photodetectors disclosed herein may be well suited for high-power and/or high-speed optical telecom applications.

In some embodiments, several photodetectors, each equipped with a respective optical multi-feed structure, can be arranged on a common substrate or base to form a traveling-wave photodetector (TWPD) array. This arrangement may further boost the power-handling capability of the resulting photodetector while advantageously preserving the beneficial high-speed performance supported by each of the individual photodetectors employed therein.

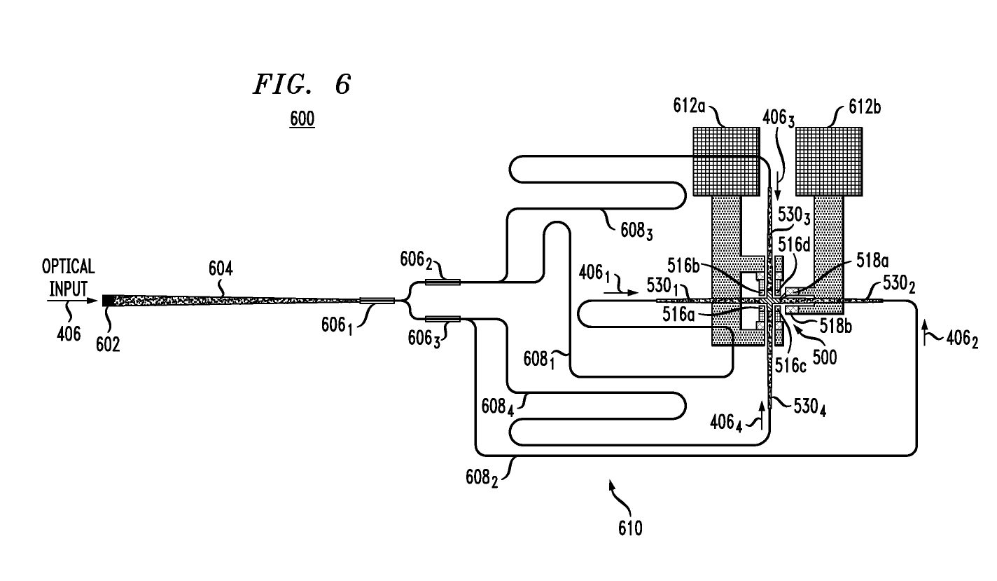

FIG. 1 shows a block diagram of a photodetector 100 according to an embodiment of the disclosure. Photodetector 100 comprises a photodiode (PD) area 110 coupled to optical feed structures 104₁ and 104₂. Optical feed structure 104₁ provides an optical interface between an optical waveguide 102₁ and PD area 110 that is configured to receive light from optical waveguide 102₁ and distribute the received light over a portion 108₁ of PD area 110. Optical feed structure 104₂ similarly provides an optical interface between an optical waveguide 102₂ and PD area 110 that is configured to receive light from optical waveguide 102₂ and distribute the received light over a portion 108₂ of PD area 110. In an example embodiment, optical waveguides 102₁ and 102₂ are configured to apply to portions 108₁ and 108₂ attenuated copies 106₁ and 106₂, respectively, of an optical signal generated by a common optical source (COS), e.g., an external optical transmitter (not explicitly shown in FIG. 1), and/or applied to these optical waveguides through a common optical input port (not explicitly shown in FIG. 1; see, e.g., FIG. 6). In response to optical signals 106₁ and 106₂, PD area 110 generates a corresponding electrical signal (e.g., electrical current or voltage) 116 that is retrieved from photodetector 100 via an electrical output port 112.

In operation, the light applied to PD area 110 by optical feed structures 104₁ and 104₂ is absorbed in the semiconductor material(s) therein, which causes the light intensity to drop as the distance from the entry point or surface defined by optical feed structure 104 increases. Hence, the boundary of a portion 108 may not correspond to any particular physical structure in PD area 110. Rather, this boundary may simply represent a virtual surface inside PD area 110 at which the light intensity has dropped down to a predetermined fraction (e.g., 10%) of the initial light intensity delivered by the corresponding optical waveguide 102 to the PD area through optical feed structure 104. In an example embodiment, the size and shape of PD area 110 are selected in a manner that causes portions 108₁ and 108₂ not to overlap at all or have a relatively small (e.g., <20%) overlap of their areas or volumes. A person of ordinary skill in the art will understand that this configuration of PD area 110 may be beneficial in terms of causing the saturation level of the generated photocurrent to be relatively high and/or reducing possible local overheating in the PD area caused by light absorption therein.

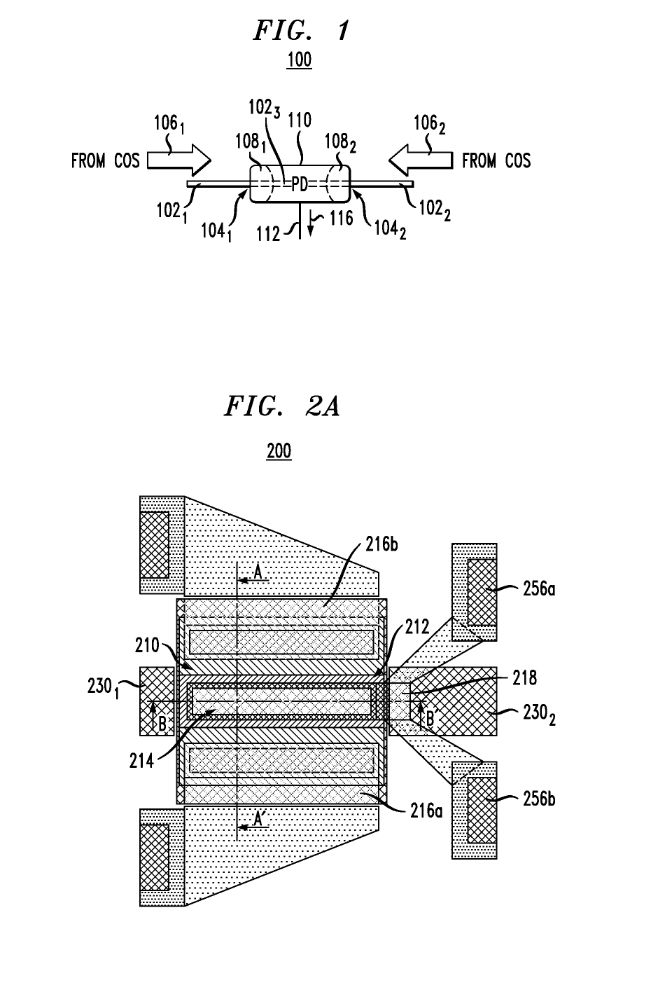

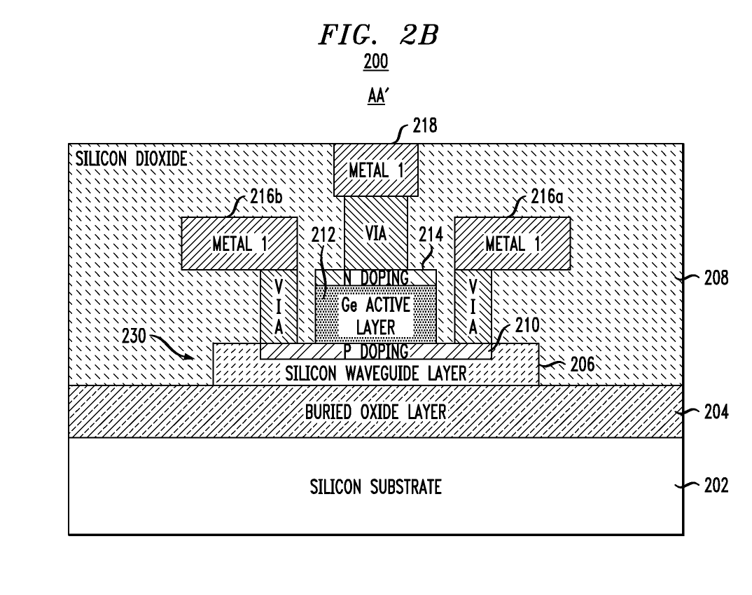

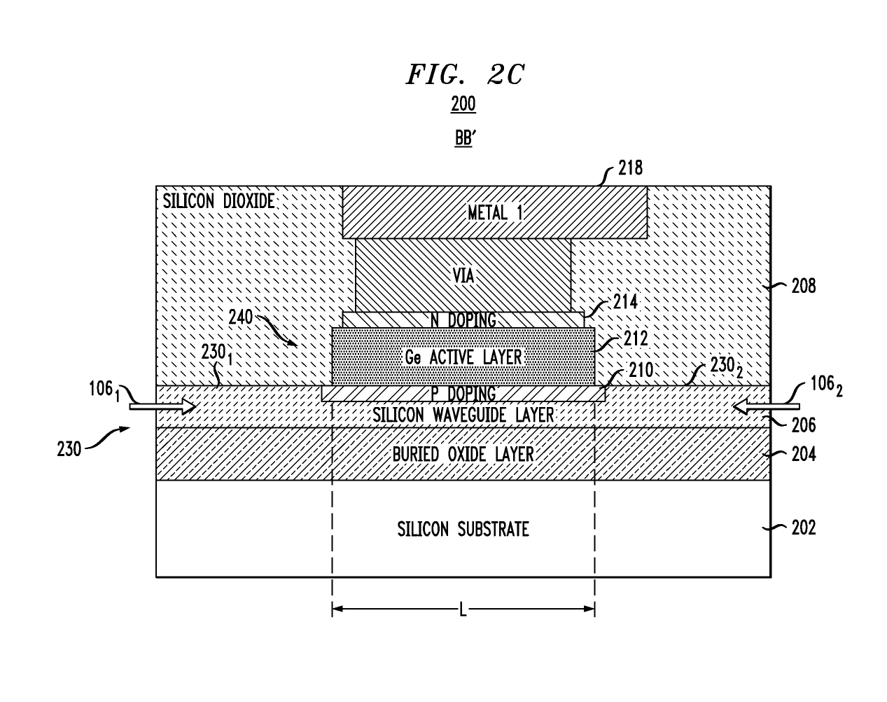

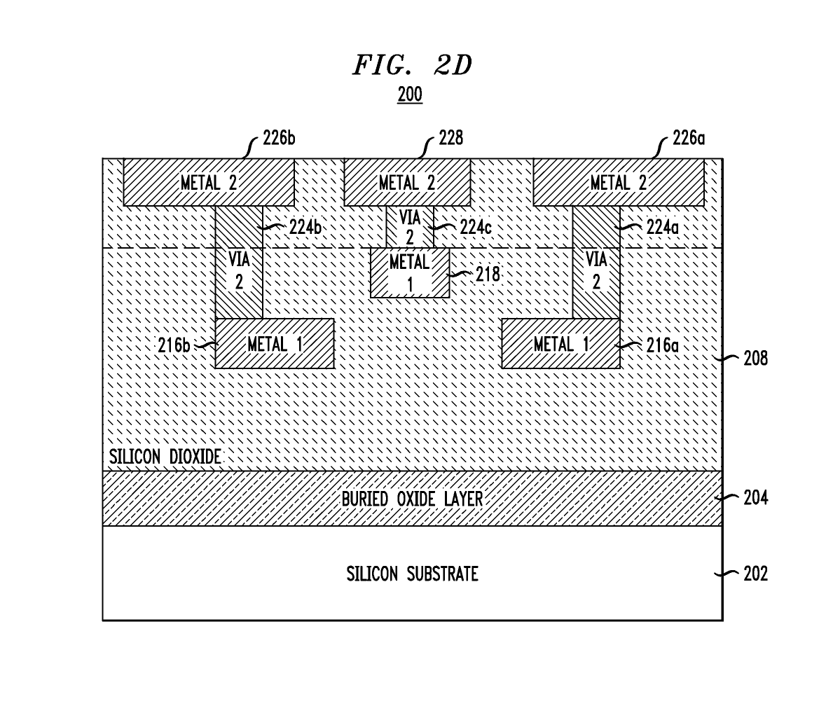

In some embodiments, optical waveguides 102₁ and 102₂ may be connected to one another by an (optional) optical waveguide 102₃. Optical waveguide 102₃ may be formed to be adjacent to PD area 110, e.g., as further illustrated in FIGS. 2A-2D. In some embodiments, optical waveguides 102₁, 102₂, and 102₃ may have nominally identical transverse cross-sections (e.g., cross-sections that are orthogonal to the intended light propagation direction in the waveguide) and connected to one another to form a single continuous optical waveguide, with optical waveguides 102₁, 102₂, and 102₃ being respective portions of that single continuous optical waveguide.

FIGS. 2A-2D show various schematic views of a semiconductor device 200 that can be used to implement photodetector 100 (FIG. 1) according to an embodiment of the disclosure. More specifically, FIG. 2A shows a schematic top view of device 200. FIGS. 2B and 2C show schematic cross-sectional side views of device 200 along two respective cross-section planes indicated in FIG. 2A by the dashed lines labeled AA′ and BB′, respectively. FIG. 2D shows a schematic cross-sectional side view of device 200 that illustrates an example metal interconnect structure that can be used in some embodiments disclosed herein.

Device 200 can be manufactured using a silicon-on-insulator (SOI) wafer comprising a silicon substrate 202, an insulator layer 204 made of silicon dioxide, and a silicon layer 206 formed over the insulator layer (see, e.g., FIGS. 2B-2C). Silicon layer 206 is patterned and etched to form an optical waveguide 230, wherein the patterned and etched silicon layer 206 serves as an optical core of the waveguide, and adjacent portions of oxide layers 204 and 208 serve as an optical cladding of the waveguide. A middle portion 210 of the patterned and etched silicon layer 206 is p-doped and is a part of a vertical photodiode structure 240. Vertical photodiode structure 240 also includes (i) a germanium layer 212 formed over portion 210 and (ii) an n-semiconductor layer 214 formed over the germanium layer (see FIGS. 2B-2C). In some embodiments, germanium layer 212 may comprise two or more differently doped germanium sub-layers (e.g., p, i, and n sub-layers; not explicitly shown in FIGS. 2A-2C).

Herein, the term “vertical” is used strictly to facilitate the description of embodiments of device 200 and is not intended to limit the embodiments to a particular orientation. For example, in the schematic views shown in FIGS. 2B-2D, a vertical or “up” direction corresponds to the direction along which the thickness of the multi-layer structure of device 200 is conventionally measured. As such, the term “vertical” identifies just a selected one of the three dimensions of the overall three-dimensional structure of device 200. The thickness of the multi-layer structure would be along the “vertical” direction where the layers are oriented horizontally, but would be along the horizontal direction where the layers are oriented vertically. Similarly, while FIGS. 2B-2D show the different layers as horizontal layers, such orientation is for descriptive purposes only and is not to be construed as a limitation.

Vertical photodiode structure 240 is designed and spatially configured to disrupt the confinement of light guided through the optical core of optical waveguide 230, thereby causing that optical waveguide to be effectively divided into two relatively weakly optically coupled waveguides 230₁ and 230₂. Due to this disruption in the confinement, the light (e.g., optical signal 106₁) coupled into waveguide 230₁ expands into vertical photodiode structure 240 at one end thereof and is absorbed in germanium layer 212. The light (e.g., optical signal 106₂) coupled into waveguide 230₂ similarly expands into vertical photodiode structure 240 at the other end thereof and is also absorbed in germanium layer 212. The electrical carriers (e.g., electrons and holes) generated by the absorbed light are spatially separated by the electric field inside vertical photodiode structure 240, thereby generating an electrical current that flows, e.g., from electrodes 216a and 216b to an electrode 218 (see FIGS. 2B-2D). This electrical current is an embodiment of electrical signal 116 (FIG. 1) and can be retrieved from device 200 using electrical conductors 226a, 226b, and 228, e.g., as indicated in FIG. 2D.

A person of ordinary skill in the art will understand that electrical conductors 226a, 226b, and 228 (FIG. 2D) represent an embodiment of electrical output port 112 (FIG. 1). Note that for clarity of depiction, electrical conductors 226a, 226b, and 228 and electrically conducting vias 224a, 224b, and 224c shown in FIG. 2D are not shown in FIGS. 2B-2C. A person of ordinary skill in the art will further understand that optical waveguides 230₁ and 230₂ (see FIGS. 2A and 2C) are embodiments of optical waveguides 102₁ and 102₂, respectively (FIG. 1).

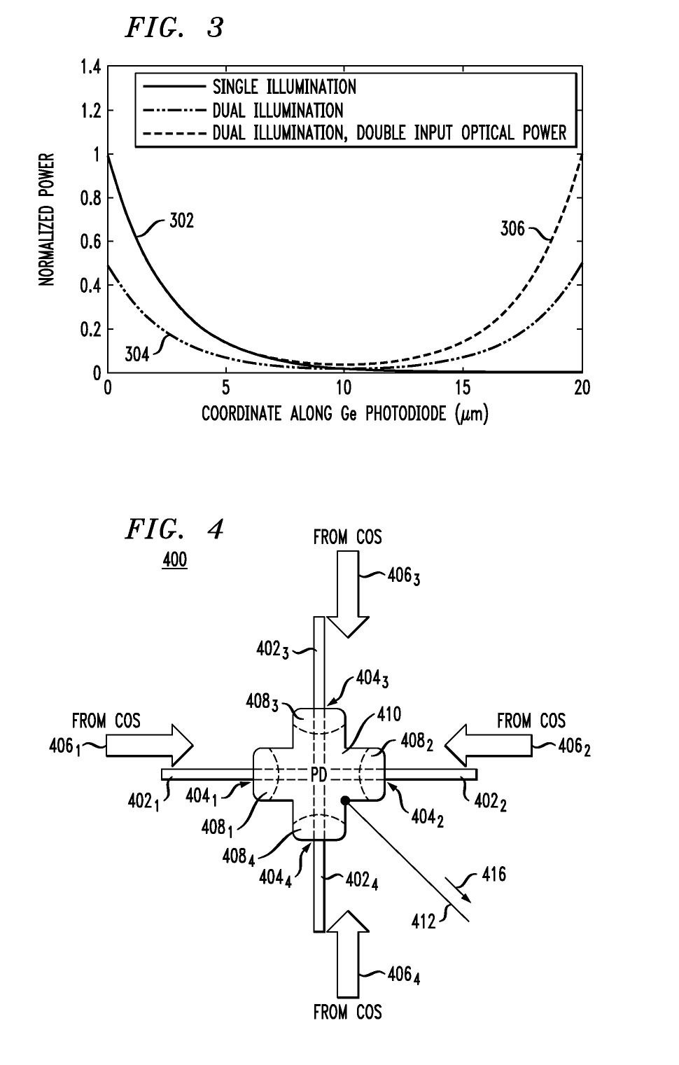

FIG. 3 graphically shows example results of computer simulations corresponding to device 200 (FIGS. 2A-2D) according to an embodiment of the disclosure. These results were obtained under the assumption that germanium layer 212 has a light-absorption coefficient α=4000 cm⁻¹ and a length L=20 μm, which length is indicated by the double-headed arrow labeled L in FIG. 2C. A person of ordinary skill in the art will understand that computer-simulation results similar to those shown in FIG. 3 can be used, e.g., as guidance for selecting the appropriate length L for vertical photodiode structure 240 at the design stage of the device production.

A solid curve 302 graphically shows light intensity in germanium layer 212 when a single beam of light of intensity I₀ is applied to vertical photodiode structure 240 through optical waveguide 230₁. Note that it takes about 10 μm of the length to substantially fully absorb the light applied in this manner.

A solid curve 304 similarly graphically shows light intensity in germanium layer 212 when a beam of light of intensity I₀ is first split into two sub-beams of equal intensity, e.g., using an optical beam splitter, and then the two sub-beams are applied to vertical photodiode structure 240 through optical waveguides 230₁ and 230₂, respectively. Curve 304 indicates that both sub-beams are absorbed substantially fully before either of them reaches the middle of germanium layer 212. Curve 304 further indicates that the light applied in this manner causes vertical photodiode structure 240 to have two substantially non-overlapping portions that are qualitatively similar to portions 108₁ and 108₂ indicated in FIG. 1.

Although both device configurations corresponding to curves 302 and 304 cause substantially all of the applied light to be absorbed in germanium layer 212, the configuration corresponding to curve 304 causes the overall light intensity in the germanium layer to be much lower than that in the configuration corresponding to curve 302. As a result, the configuration corresponding to curve 304 may help to reduce possible detrimental effects caused by the photocurrent saturation and/or photodiode overheating. If the intensity I₀ is sufficiently low to avoid these detrimental effects in the configuration corresponding to curve 302, then device 200 enables the optical power of the incoming optical signal to be effectively doubled to the intensity 2I₀ without causing an onset of these detrimental effects, because the doubled optical power can be divided between two sub-beams and then applied to vertical photodiode structure 240 at opposite ends thereof, thereby causing the effective maximum light intensity not to exceed I₀, e.g., as indicated in FIG. 3 by a dashed curve 306.

More specifically, dashed curve 306 shows light intensity in germanium layer 212 when a beam of light of intensity 2I₀ is first split into two sub-beams of equal intensity, e.g., using an optical beam splitter, and then the two sub-beams are applied to vertical photodiode structure 240 through optical waveguides 230₁ and 230₂, respectively. Curve 306 indicates that the two sub-beams generate an intensity profile having two symmetric portions in germanium layer 212, with each portion being very similar to the intensity profile shown by curve 302. As such, the configuration corresponding to curve 306 is unlikely to cause more-pronounced detrimental effects than the configuration corresponding to curve 302.

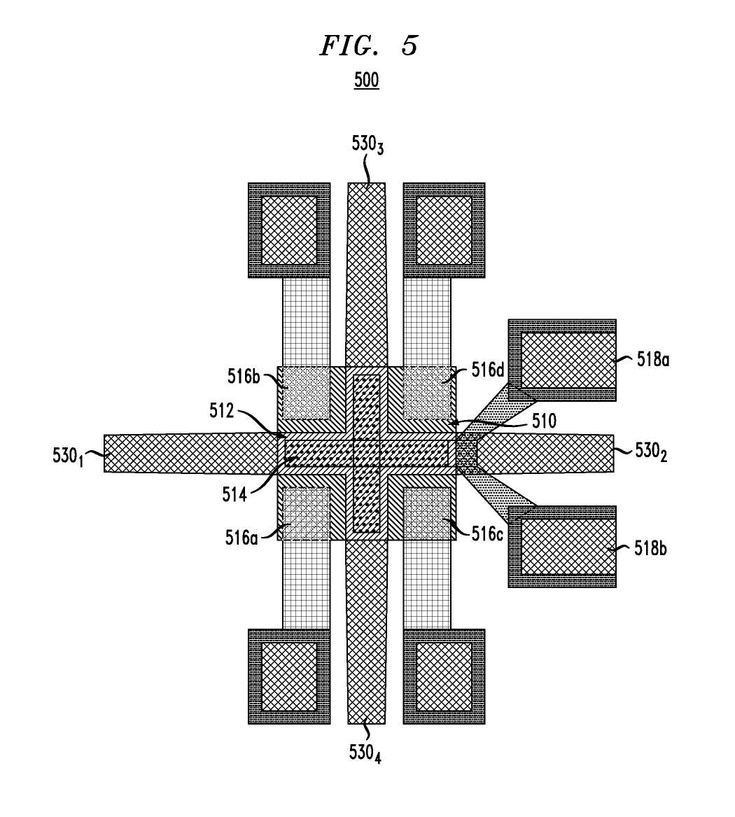

FIG. 4 shows a block diagram of a photodetector 400 according to an alternative embodiment of the disclosure. Photodetector 400 is generally analogous to photodetector 100 (FIG. 1), and analogous elements of the two photodetectors are labeled using numerical labels having the same last two digits. However, photodetector 400 differs from photodetector 100 in that a PD area 410 of photodetector 400 is coupled to four (rather than two) optical waveguides 402₁-402₄ via four corresponding optical feed structures 404₁-404₄. A person of ordinary skill in the art will understand how to design and build photodetector 400 using the inventive concepts already described above in reference to FIGS. 1-3 in a manner that enables an increase in the number of separate optical feeds for the PD area of the photodetector from two to four.

For example, an embodiment of photodetector 400 may be constructed by joining together the corresponding structures of two photodetectors 100 oriented at 90 degrees with respect to one another. With this approach to constructing photodetector 400, the shape of some electrodes, such as electrodes 216a and 216b (see FIG. 2A), may need to be changed. A second set of some other electrodes, such as electrodes 256a and 256b (also see FIG. 2A), may not need to be added to avoid redundancy. A representative result of this approach to constructing an embodiment of photodetector 400 is further illustrated in FIG. 5.

FIG. 5 shows a schematic top view of a semiconductor device 500 that can be used to implement photodetector 400 (FIG. 4) according to an embodiment of the disclosure. Device 500 is generally analogous to device 200 (FIGS. 2A-2D), and analogous elements of the two devices are labeled using numerical labels having the same last two digits. Cross-sectional views of device 500 (not shown) are generally similar to cross-sectional views of device 200 shown in FIGS. 2B-2D.

Similar to device 200 (see FIGS. 2B-2D), device 500 can be manufactured using a silicon-on-insulator (SOI) wafer. For example, a silicon overlayer of the SOI wafer can be patterned, etched, and clad to form optical waveguides 530₁-530₄. As indicated in FIG. 5, optical waveguides 530₁-530₄ are in a cross-like arrangement, wherein: (i) waveguides 530₁ and 530₂ are collinear with one another; (ii) waveguides 5303 and 530₄ are also collinear with one another; and (iii) waveguides 530₁/530₂ are orthogonal to waveguides 530₃/530₄. A vertical photodiode structure similar to vertical photodiode structure 240 (see, e.g., FIGS. 2B-2C) can be fabricated in device 500 by: (i) p-doping the silicon core of optical waveguides 530₁-530₄ near their intersection to generate a thin film 510 of doped silicon thereon; (ii) forming a germanium layer 512 over the doped film 510; (iii) forming an n-semiconductor layer 514 over the germanium layer 512. Electrodes 516a-516d can then be formed and electrically connected to film 510 using a metal interconnect structure similar to the metal interconnect structure shown in FIGS. 2B and 2D. Electrodes 518a and 518b can similarly be formed and electrically connected to n-semiconductor layer 514.

FIG. 6 shows a schematic top view of a planar electro-optical circuit 600 that incorporates semiconductor device 500 (FIG. 5) according to an embodiment of the disclosure. In addition to device 500 (FIG. 5), electro-optical circuit 600 includes an optical waveguide circuit 610. Electrodes 516a-516d of device 500 are all electrically connected, as indicated in FIG. 6, to a peripheral metal pad 612a. Electrodes 518a and 518b of device 500 are similarly electrically connected, as indicated in FIG. 6, to a peripheral metal pad 612b. Pads 612a/612b represent an embodiment of an electrical output port 412, which is configured in photodetector 400 to output an electrical output signal 416 generated using PD area 410 (see FIG. 4).

Optical waveguide circuit 610 comprises an optical input port 602 configured to operate as a common optical source (COS) for the optical multi-feed structure of device 500. More specifically, optical input port 602 may be configured to receive an optical input signal 406. Waveguide circuit 610 then operates to optically split optical input signal 406 into four attenuated copies 406₁-406₄ (also see FIG. 4) and apply these four attenuated copies to optical waveguides 530₁-530₄, respectively, of device 500, e.g., as indicated in FIG. 6.

An optical waveguide 604 connects optical input port 602 to a 3-dB optical splitter 606₁. The two outputs of optical splitter 606₁ are connected to the inputs of 3-dB optical splitters 606₂ and 606₃, respectively. The four outputs of optical splitters 606₂ and 606₃ are connected to optical waveguides 608₁-608₄ that are further connected to optical waveguides 530₁-530₄, respectively, of device 500. In an example embodiment, optical waveguides 608₁-608₄ have equal lengths to provide synchronous arrival of signal copies 406₁-406₄ to the PD area of device 500.

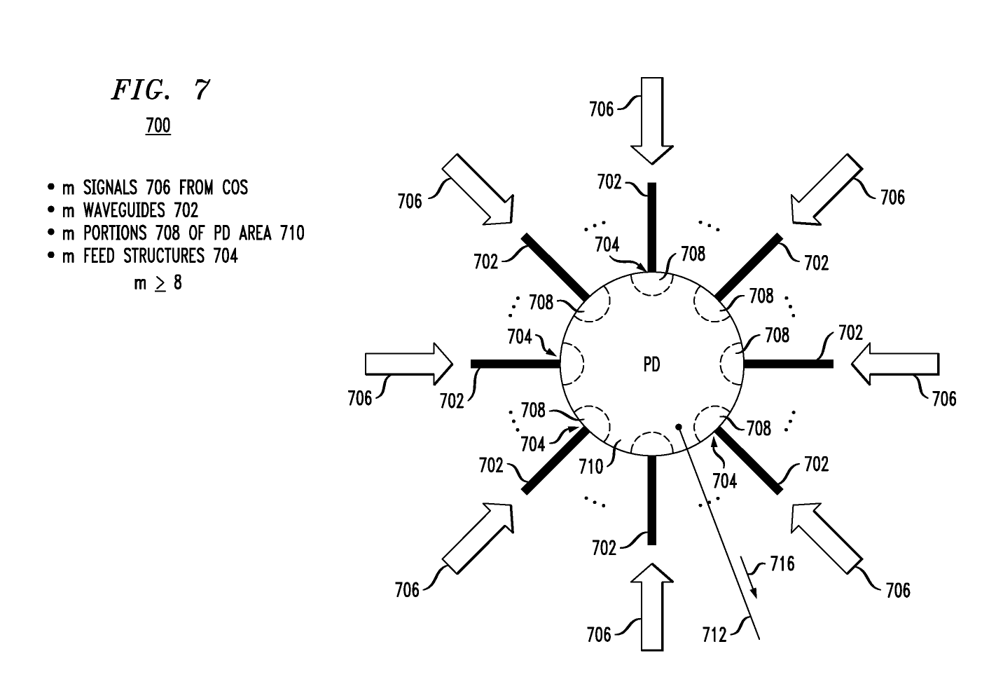

FIG. 7 shows a block diagram of a photodetector 700 according to another alternative embodiment of the disclosure. Photodetector 700 is generally analogous to photodetectors 100 (FIG. 1) and 400 (FIG. 4), and analogous elements of these photodetectors are labeled using numerical labels having the same last two digits. However, photodetector 400 differs from photodetectors 100 and 400 in that a PD area 710 in photodetector 700 is coupled to m optical waveguides 702 via m corresponding optical feed structures 704, where m is a positive integer greater than seven. A person of ordinary skill in the art will appreciate that photodetector 700 may be designed and built using the inventive concepts already described above in reference to FIGS. 1-6, but also applying these concepts in a manner that enables an increase in the number of separate optical feeds for the PD area of the photodetector to any number m>4 (the upper limit of which may be subject to practical geometric constrains).

A PD area 710 in photodetector 700 is coupled to m optical waveguides 702 via m corresponding optical feed structures 704. Each optical feed structure 704 is configured to receive light from a respective optical waveguide 702 and distribute the received light over a respective portion 708 of PD area 710. In operation, each of the m optical waveguides 702 may be configured to receive a respective (e.g., attenuated) copy 706 of an optical input signal, as indicated in FIG. 7. In an example embodiment, the optical input signal may be supplied, e.g., by a common optical source (COS, not explicitly shown in FIG. 7). In response to optical signals 706, PD area 710 generates an electrical output signal 716 that can be retrieved from photodetector 700 via an electrical output port 712.

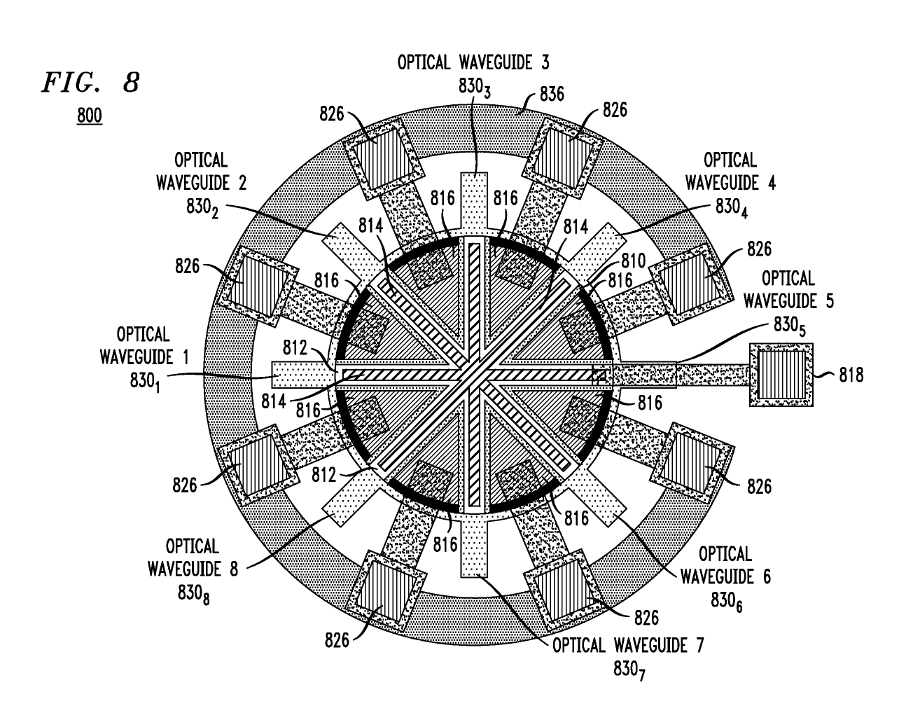

FIG. 8 shows a schematic top view of a semiconductor device 800 that can be used to implement an embodiment of photodetector 700 (FIG. 7) corresponding to m=8 according to an embodiment of the disclosure. Device 800 is generally analogous to devices 200 (FIGS. 2A-2D) and 500 (FIG. 5), and analogous elements of these devices are labeled using numerical labels having the same last two digits. Cross-sectional views of device 800 (not shown) are generally similar to cross-sectional views of device 200 shown in FIGS. 2B-2D.

Similar to devices 200 and 500 (see FIGS. 2 and 5), device 800 can be manufactured using a silicon-on-insulator (SOI) wafer. For example, a silicon layer of the SOI wafer can be patterned, etched, and clad to form optical waveguides 830₁-830₈. As indicated in FIG. 8, optical waveguides 830₁-830₈ are in a star-like arrangement, wherein adjacent waveguides are oriented at 45 degrees with respect to one another. A vertical photodiode structure similar to vertical photodiode structure 240 (see, e.g., FIGS. 2B-2C) can be fabricated in device 800 by: (i) p-doping the silicon core of optical waveguides 830₁-830₈ near their intersection to generate a thin film 810 of doped silicon thereon; (ii) forming a germanium layer 812 over the doped film 810; (iii) forming an n-semiconductor layer 814 over the germanium layer 812. Eight electrodes 816 can be formed and electrically connected to film 810 using a metal interconnect structure similar to the metal interconnect structure shown in FIGS. 2B and 2D. Electrode 818 can similarly be formed and electrically connected to n-semiconductor layer 814. Electrodes 816 can further be electrically connected to one another using metal terminals 826 and a circular electrically conducting track 836. One of metal terminals 826 and electrode 818 can then further be connected to respective wires (not explicitly shown in FIG. 8) to form an electrical output port for device 800. A person of ordinary skill in the art will understand that this electrical output port is an embodiment of electrical output port 712 (see FIG. 7).

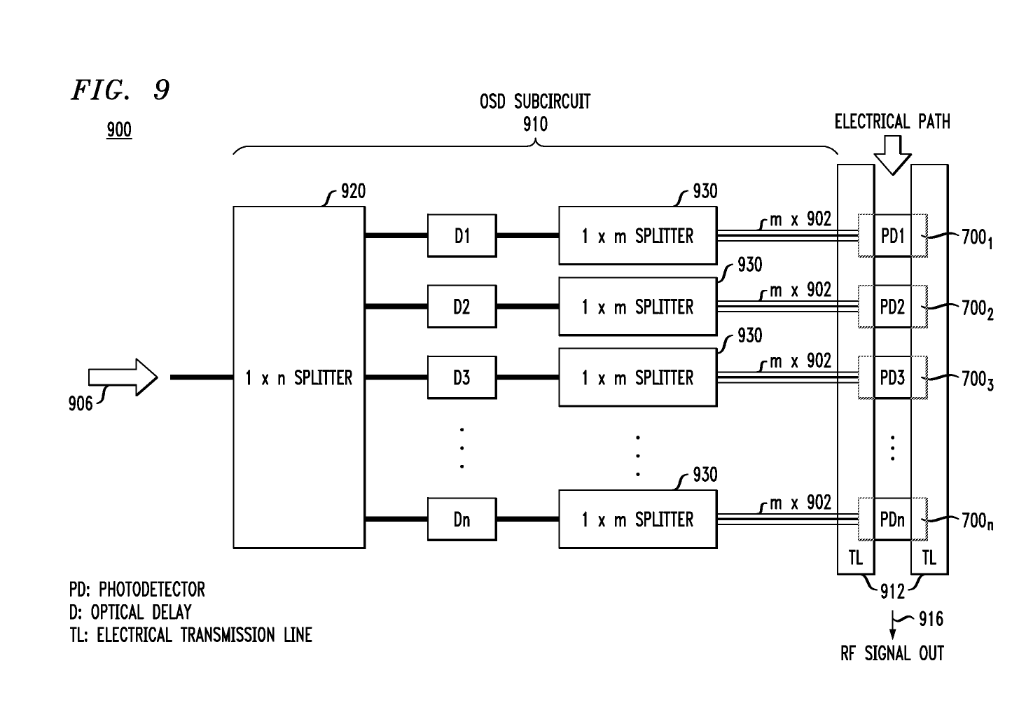

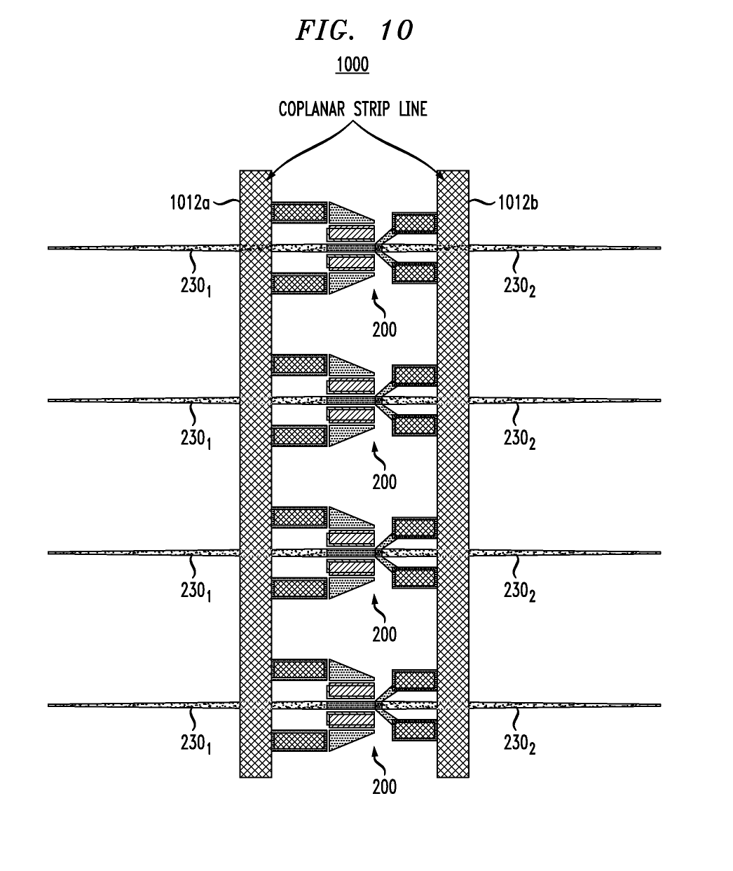

FIG. 9 shows a block diagram of a traveling-wave photodetector (TWPD) circuit 900 according to an embodiment of the disclosure. Circuit 900 comprises n arrayed photodetectors 700 (FIG. 7), each coupled to m optical waveguides 902 in a manner that causes each of the m optical waveguides 702 therein (see FIG. 7) to receive light from a respective one of the m optical waveguides 902. A person of ordinary skill in the art will understand that, in various embodiments, n can be any (practical) positive integer greater than one, and m can be any (practical) positive integer greater than one.

Circuit 900 further comprises an optical signal-distribution (OSD) sub-circuit 910 configured to generate n×m attenuated copies of an optical input signal 906 and couple each of the generated signal copies into a respective one of the n×m optical waveguides 902 for delivery to photodetectors 700₁-700ₙ. OSD sub-circuit 910 generates the n×m attenuated copies of optical input signal 906 using a 1×n optical splitter 920 and n 1×m optical splitters 930 interconnected as indicated in FIG. 9. OSD sub-circuit 910 also includes n optical delay elements D1-Dn configured to apply different respective delays to different respective subsets of attenuated copies of optical input signal 906. In an example embodiment, the time delays imposed by optical delay elements D1-Dn are selected to cause the electrical RF signals 716 generated by individual photodetectors 700 in response to the light received through OSD sub-circuit 910 to add constructively (e.g., in phase) at an electrical transmission line 912 connected to electrical output ports 712 of the photodetectors. A person of ordinary skill in the art will understand how to select the delays for delay elements D1-Dn, e.g., based on the group velocities of the attenuated copies of optical input signal 906 in OSD sub-circuit 910 and the group velocity of the corresponding electrical RF signals 716 on electrical transmission line 912. A person of ordinary skill in the art will further understand that the constructive addition of the electrical RF signals 716 generated by different individual photodetectors 700 advantageously causes a resulting electrical output signal 916 generated by TWPD circuit 900 in response to optical input signal 906 to be relatively strong and/or have a good signal-to-noise ratio.

In a possible embodiment, delay element D1 may have a nominally zero insertion-delay time and, as such, can be removed from OSD sub-circuit 910.

FIG. 10 shows a schematic top view of a semiconductor device 1000 that can be used to implement a photodetector array for a TWPD circuit similar to TWPD circuit 900 (FIG. 9) according to an embodiment of the disclosure. For example, device 1000 can be used in a TWPD circuit wherein device 1000 is optically coupled to an embodiment of OSD sub-circuit 910 (see FIG. 9) corresponding to n=4 and m=2. Alternative OSD sub-circuits can similarly be used with semiconductor device 1000 to form the corresponding alternative TWPD circuits.

In an example embodiment, device 1000 includes four instances (e.g., nominal copies) of device 200 (FIGS. 2A-2D), all fabricated on a common semiconductor substrate similar to substrate 202 (see, e.g., FIGS. 2B and 2C) and arrayed as indicated in FIG. 10. Device 1000 further includes coplanar conductor strips 1012a and 1012b that electrically connect the four devices 200. More specifically, strip 1012a electrically connects electrodes 216 of the four devices 200 (also see FIG. 2A). Strip 1012b similarly electrically connects electrodes 218 of the four devices 200 (also see FIG. 2A). Together, coplanar conductor strips 1012a and 1012b operate as a microwave transmission line that can be used to retrieve the electrical output signal generated by device 1000 in response to light applied, through the corresponding four optical waveguides 230₁ and four optical waveguides 230₂, to the four arrayed devices 200 therein.

An example embodiment of device 1000 was fabricated using the silicon photonic technology and experimentally tested to assess the extent of benefits and advantages of the disclosed TWPD circuits. The obtained experimental results indicate that the use of optical multi-feed structures, such as the dual-feed structures of photodetectors 200 in device 1000, offers several important advantages for high-power operation, such as: (i) the number of optical channels can be doubled; (ii) the absorbing semiconductor region is more efficiently used; and (iii) adverse effects caused by the heat generated due to the absorbed light are alleviated because the heat is more-uniformly distributed over the active PD area.

For one embodiment of device 1000, we demonstrated a maximum DC saturation current of 112 mA at a bias voltage of −3V applied to the vertical PD structures thereof. The traveling-wave design ensures high-speed operation, such as a 3-dB bandwidth of about 25 GHz at −3 V and 6 mA. We also established that some embodiments of the disclosed TWPD circuits can generate the electrical RF power of about 12 dBm at low frequencies and above 5 dBm at 20 GHz, which corresponds to an advantageously high power-bandwidth area density value of 0.66 mW-GHz/μm².

According to an example embodiment disclosed above in reference to FIGS. 1-10, provided is an apparatus (e.g., 100, FIG. 1; 200, FIG. 2; 400, FIG. 4; 500, FIG. 5; 600, FIG. 6; 700, FIG. 7; 800, FIG. 8; 900, FIG. 9; 1000, FIG. 10) comprising: a photodiode (e.g., 240, FIG. 2C) that comprises an active semiconductor layer (e.g., 212, FIG. 2C); a first optical waveguide (e.g., 102₁, FIG. 1; 230₁, FIG. 2A) configured to couple light into a first portion (e.g., 108₁, FIG. 1) of the active semiconductor layer; and a second optical waveguide (e.g., 102₂, FIG. 1; 230₂, FIG. 2A) configured to couple light into a second portion (e.g., 108₂, FIG. 1) of the active semiconductor layer different from the first portion.

As used herein, the term “active semiconductor layer” refers to a semiconductor structure or piece of material that is configured to convert light shone thereon into electrical current. In an example embodiment, an active semiconductor layer comprises two or more sub-layers that form a p-n junction or a PIN (positive-intrinsic-negative) structure. The sub-layers can be fabricated, e.g., using different types of doping of the same semiconductor material or different semiconductor materials. Electrically conducting electrodes, which are conventionally referred to as the cathode and anode, are typically placed in close proximity to the active semiconductor layer to collect charge carriers (electrons or holes) generated by the active semiconductor layer when light is shone thereon. These electrodes are not considered to be a part of the “active semiconductor layer.” When a photon of sufficient energy strikes and is absorbed in the active semiconductor layer, it creates an electron-hole pair. If the absorption occurs in or near the depletion region, then the electron-hole pair is spatially separated therein by the corresponding built-in electric field, with the hole moving toward the anode, and the electron moving toward the cathode, thereby generating a photocurrent.

In some embodiments of the above apparatus, the active semiconductor layer is continuous between the first and second portions (e.g., as shown in FIG. 2C).

In some embodiments of any of the above apparatus, the active semiconductor layer has a size (e.g., L, FIG. 2C) that causes the first and second portions not to overlap (e.g., as indicated in FIGS. 1 and 3).

In some embodiments of any of the above apparatus, the active semiconductor layer has a size (e.g., L, FIG. 2C) that causes the first and second portions to overlap by no more than 20%.

In some embodiments of any of the above apparatus, the apparatus further comprises a third optical waveguide (e.g., 102₃, FIG. 1) that connects the first optical waveguide and the second optical waveguide.

In some embodiments of any of the above apparatus, the active semiconductor layer is adjacent to the third optical waveguide (e.g., as shown in FIGS. 2B and 2C).

In some embodiments of any of the above apparatus, the apparatus further comprises a substrate (e.g., 202, FIGS. 2B and 2C), wherein: the third optical waveguide is supported at a first offset distance from the substrate; the active semiconductor layer is supported at a second offset distance from the substrate, the second offset distance being greater than the first offset distance; and the substrate, the photodiode, the first, second, and third waveguides are all parts of a monolithic integrated circuit (e.g., as shown in FIGS. 2A-2D).

In some embodiments of any of the above apparatus, the first and second optical waveguides are supported at the first offset distance from the substrate.

In some embodiments of any of the above apparatus, the apparatus further comprises one or more additional optical waveguides (e.g., 830, FIG. 8), each configured to couple light into a different respective portion (e.g., 408, FIG. 4; 708, FIG. 7) of the active semiconductor layer.

In some embodiments of any of the above apparatus, the apparatus further comprises an optical-waveguide structure (e.g., star-shaped waveguide structure in FIG. 8) adjacent to the active semiconductor layer and configured to optically connect the first optical waveguide, the second optical waveguide, and the one or more additional optical waveguides.

In some embodiments of any of the above apparatus, the one or more additional optical waveguides include at least two optical waveguides (e.g., 830₃-830₄, FIG. 8).

In some embodiments of any of the above apparatus, the one or more additional optical waveguides include at least six optical waveguides (e.g., 830₃-830₈, FIG. 8).

In some embodiments of any of the above apparatus, the apparatus further comprises an optical waveguide circuit (e.g., 610, FIG. 6) configured to generate two or more copies of an optical input signal (e.g., 406, FIG. 6) and apply a first (e.g., 406₁, FIG. 6) of the two or more copies to the first optical waveguide and a second (e.g., 406₂, FIG. 6) of the two or more copies to the second optical waveguide.

In some embodiments of any of the above apparatus, the optical waveguide circuit comprises one or more optical power splitters (e.g., 606, FIG. 6) configured to optically split the optical input signal into the two or more copies, each of said two or more copies being an attenuated copy of the optical input signal.

In some embodiments of any of the above apparatus, the optical waveguide circuit is configured to cause the first and second optical waveguides to apply the first and second copies of the optical input signal to the active semiconductor layer with nominally identical respective time delays.

In some embodiments of any of the above apparatus, the photodiode, the first optical waveguide, and the second optical waveguide are parts of a first photodetector (e.g., 700₁, FIG. 9); and wherein the apparatus further comprises: a second photodetector (e.g., 700₂, FIG. 9) that is nominally identical to the first photodetector; and an electrical transmission line (e.g., 912, FIG. 9) configured to collect (i) a first electrical signal generated by the first photodetector in response to the light coupled by the first and second optical waveguides into the active semiconductor layer in the first photodetector and (ii) a second electrical signal generated by the second photodetector in response to light coupled by first and second optical waveguides of the second photodetector into an active semiconductor layer in the second photodetector.

In some embodiments of any of the above apparatus, the apparatus further comprises an optical signal-distribution sub-circuit (e.g., 910, FIG. 9) configured to: (i) optically split an optical input signal (e.g., 906, FIG. 9) to generate a first attenuated copy of the optical input signal and a second attenuated copy of the optical input signal; (ii) apply the first attenuated copy to the first photodetector with a first time delay (e.g., caused by D1, FIG. 9); and (iii) apply the second attenuated copy to the second photodetector with a second time delay (e.g., caused by D2, FIG. 9) different from the first time delay.

In some embodiments of any of the above apparatus, said different respective time delays are selected to cause the first electrical signal and the second electrical signal to add in phase on the electrical transmission line.

In some embodiments of any of the above apparatus, the apparatus further comprises one or more additional photodetectors (e.g., 700₃-700ₙ, FIG. 9), each nominally identical to the first photodetector, wherein the electrical transmission line is further configured to collect one or more respective additional electrical signals generated by the one or more additional photodetectors in response to light applied thereto.

In some embodiments of any of the above apparatus, the apparatus further comprises an optical signal-distribution sub-circuit (e.g., 910, FIG. 9) configured to apply a plurality of attenuated copies of an optical input signal (e.g., 906, FIG. 9) to the first photodetector, the second photodetector, and the one or more additional photodetectors with different respective time delays (e.g., imposed by D1-Dn, FIG. 9) that cause the first electrical signal, the second electrical signal, and the one or more respective additional electrical signals to add constructively on the electrical transmission line to generate a combined electrical output signal responsive to the optical input signal.

While this disclosure includes references to illustrative embodiments, this specification is not intended to be construed in a limiting sense. Various modifications of the described embodiments, as well as other embodiments within the scope of the disclosure, which are apparent to persons skilled in the art to which the disclosure pertains are deemed to lie within the principle and scope of the disclosure.

Some embodiments may be implemented as circuit-based processes, including possible implementation on a single integrated circuit.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain the nature of this disclosure may be made by those skilled in the art without departing from the scope of the disclosure, e.g., as expressed in the following claims.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the disclosure. The appearances of the phrase “in one embodiment” in various places in the specification are not necessarily all referring to the same embodiment, nor are separate or alternative embodiments necessarily mutually exclusive of other embodiments. The same applies to the term “implementation.”

Throughout the detailed description, the drawings, which are not to scale, are illustrative only and are used in order to explain, rather than limit the disclosure. The use of terms such as height, length, width, top, bottom, is strictly to facilitate the description of the embodiments and is not intended to limit the embodiments to a specific orientation. For example, height does not imply only a vertical rise limitation, but is used to identify one of the three dimensions of a three dimensional structure as shown in the figures. Such “height” would be vertical where the device layers are horizontal but would be horizontal where the device layers are vertical, and so on. Similarly, while some figures show the different layers as horizontal layers such orientation is for descriptive purpose only and not to be construed as a limitation.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term compatible means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

The described embodiments are to be considered in all respects as only illustrative and not restrictive. In particular, the scope of the disclosure is indicated by the appended claims rather than by the description and figures herein. All changes that come within the meaning and range of equivalency of the claims are to be embraced within their scope.

The description and drawings merely illustrate the principles of the disclosure. It will thus be appreciated that those of ordinary skill in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

It should be appreciated by those of ordinary skill in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

What is claimed is:

1. An apparatus comprising:
a photodiode that comprises an active semiconductor layer;
a first optical waveguide configured to couple light into a first portion of the active semiconductor layer; and
a second optical waveguide configured to couple light into a second portion of the active semiconductor layer different from the first portion.

2. The apparatus of claim 1, wherein the active semiconductor layer is continuous between the first and second portions.

3. The apparatus of claim 2, wherein the active semiconductor layer has a size that causes the first and second portions not to overlap.

4. The apparatus of claim 2, wherein the active semiconductor layer has a size that causes the first and second portions to overlap by no more than 20%.

5. The apparatus of claim 1, further comprising a third optical waveguide that connects the first optical waveguide and the second optical waveguide.

6. The apparatus of claim 5, wherein the active semiconductor layer is adjacent to the third optical waveguide.

7. The apparatus of claim 5, further comprising a substrate, wherein:
the third optical waveguide is supported at a first offset distance from the substrate;
the active semiconductor layer is supported at a second offset distance from the substrate, the second offset distance being greater than the first offset distance; and
the substrate, the photodiode, the first, second, and third waveguides are all parts of a monolithic integrated circuit.

8. The apparatus of claim 7, wherein the first and second optical waveguides are supported at the first offset distance from the substrate.

9. The apparatus of claim 1, further comprising one or more additional optical waveguides, each configured to couple light into a different respective portion of the active semiconductor layer.

10. The apparatus of claim 9, further comprising an optical-waveguide structure adjacent to the active semiconductor layer and configured to optically connect the first optical waveguide, the second optical waveguide, and the one or more additional optical waveguides.

11. The apparatus of claim 9, wherein the one or more additional optical waveguides include at least two optical waveguides.

12. The apparatus of claim 9, wherein the one or more additional optical waveguides include at least six optical waveguides.

13. The apparatus of claim 1, further comprising an optical waveguide circuit configured to generate two or more copies of an optical input signal and apply a first of the two or more copies to the first optical waveguide and a second of the two or more copies to the second optical waveguide.

14. The apparatus of claim 13, wherein the optical waveguide circuit comprises one or more optical power splitters configured to optically split the optical input signal into the two or more copies, each of said two or more copies being an attenuated copy of the optical input signal.

15. The apparatus of claim 13, wherein the optical waveguide circuit is configured to cause the first and second optical waveguides to apply the first and second copies of the optical input signal to the active semiconductor layer with nominally identical respective time delays.

16. The apparatus of claim 1,
wherein the photodiode, the first optical waveguide, and the second optical waveguide are parts of a first photodetector; and
wherein the apparatus further comprises:
a second photodetector that is nominally identical to the first photodetector; and
an electrical transmission line configured to collect (i) a first electrical signal generated by the first photodetector in response to the light coupled by the first and second optical waveguides into the active semiconductor layer in the first photodetector and (ii) a second electrical signal generated by the second photodetector in response to light coupled by first and second optical waveguides of the second photodetector into an active semiconductor layer in the second photodetector.

17. The apparatus of claim 16, further comprising an optical signal-distribution sub-circuit configured to:
optically split an optical input signal to generate a first attenuated copy of the optical input signal and a second attenuated copy of the optical input signal;
apply the first attenuated copy to the first photodetector with a first time delay; and
apply the second attenuated copy to the second photodetector with a second time delay different from the first time delay.

18. The apparatus of claim 17, wherein said different respective time delays are selected to cause the first electrical signal and the second electrical signal to add in phase on the electrical transmission line.

19. The apparatus of claim 16, further comprising one or more additional photodetectors, each nominally identical to the first photodetector, wherein the electrical transmission line is further configured to collect one or more respective additional electrical signals generated by the one or more additional photodetectors in response to light applied thereto.

20. The apparatus of claim 19, further comprising an optical signal-distribution sub-circuit configured to apply a plurality of attenuated copies of an optical input signal to the first photodetector, the second photodetector, and the one or more additional photodetectors with different respective time delays that cause the first electrical signal, the second electrical signal, and the one or more respective additional electrical signals to add constructively on the electrical transmission line to generate a combined electrical output signal responsive to the optical input signal.
